(19) United States
(12) Patent Application Publication
(10) Pub. No.: US 2006/0227531 A1
(43) Pub. Date: Oct. 12, 2006

(54) Electroluminescent displays

(75) Inventor: Chung-Yeh Iou, Wuci Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/298,326

(22) Filed: Dec. 9, 2005

(30) Foreign Application Priority Data
Apr. 6, 2005 (TW) 94110841

(51) Int. Cl. F21V 9/16

(52) U.S. Cl. 362/84

(57) ABSTRACT

An organic light emitting diode (OLED) display comprises a substrate, an organic light emitting diode element having an organic light emitting layer disposed on the substrate. A conductive layer is disposed on the organic light emitting layer to serve as a common electrode for the OLED element. A photovoltaic cell disposed on the organic light emitting diode element, converting incident light into electricity, wherein the conductive layer serves as the common electrode for the photovoltaic cell.

### BACKGROUND

The invention relates to electroluminescent displays, and more particularly, to organic light emitting diode displays integrating photovoltaic cells.

Among flat panel displays, organic light emitting diode (OLED) displays exhibit characteristics of self-emission, high brightness, wide viewing angle, high response, simple fabrication process, low power consumption, and good outdoor reliability, and are therefore widely applied in portable computers, notebooks, mobile phones, and personal digital assistances (PDAs).

Organic light emitting diode displays exhibit self-emission with high brightness and therefore have different applications than conventional liquid crystal displays. By adopting different organic light emitting materials, full color organic light emitting diode displays can be achieved. Moreover, biasing low driving voltage, the organic light emitting diode display can be still visible at a high incline viewing angle.

Conventional organic light emitting diode displays comprise a multi-layered structure with at least one light emitting layer sandwiched between an anode and a cathode. When a bias is applied between the anode and the-cathode, electrons and holes are separately generated and then recombined at the light emitting layer, thereby generating light.

Conversely, solar energy converters such as photovoltaic cells convert environmental incident light into electricity. More specifically, as power consumption requirements become stricter, electronic devices require the integration of OLED devices and photovoltaic cell devices to deduce dependency upon a main power source.

To improve power consumption efficiency, Japanese Laid-Open Patent Application No. 2002-006769, the entirety of which is hereby incorporated by reference, discloses an organic light emitting diode display. FIG. 1 is a cross section of a conventional electronic device integrating a photovoltaic cell. An electronic device 100 comprises an organic light emitting diode device and a photovoltaic cell. The organic light emitting diode device is formed on a substrate 10. For example, a plurality of organic light emitting diode elements 20 is formed on a substrate 10. Each organic light emitting diode element 20 comprises a light emitting layer 24 interposed between a anode 22 and a cathode 26. A frame 30 passivates the organic light emitting diode device. A plurality of photovoltaic cell device

Considering the thickness of the conventional touch control panel integrated with an OLED display, touch control panel 14, OLED display 52, and the two substrates 50 and 12 and the gap 72 therebetween are space consumptive. Moreover, separately forming the touch control panel 14 and the OLED display 52 also incurs high production costs.

### SUMMARY

Accordingly, the invention provides a touch control panel integrated with an organic light emitting diode (OLED) display, capable of reducing the total thickness of electronic devices.

The invention further provides an organic light emitting diode (OLED) display, comprising an organic light emitting diode (OLED) element having an organic light emitting layer. A conductive layer is disposed on the organic light emitting layer to serve as a common electrode for the OLED element. A photovoltaic cell element is disposed on the OLED element, converting incident light into electricity to drive the OLED element, wherein- the conductive layer serves as the common electrode for the photovoltaic cell.

The invention further provides an organic light emitting diode (OLED) display, comprising a substrate. An organic light emitting diode (OLED) element having an organic light emitting layer is disposed on the substrate. A conductive layer is disposed on the organic light emitting layer to serve as a common electrode for the OLED element. A photovoltaic cell element is disposed on the OLED element, converting incident light into electricity to drive the OLED element, wherein the conductive layer serves as the common electrode for the photovoltaic cell.

The invention further provides an organic light emitting diode (OLED) display comprising a substrate. A photovoltaic cell having a charge generation layer is disposed on the substrate. A conductive layer is disposed on the charge generation layer to serve as a common electrode for the photovoltaic cell. An organic light emitting diode (OLED) element is disposed on the photovoltaic cell. The photovoltaic cell converts incident light into electricity to drive the OLED element. The conductive layer serves as the common electrode for the OLED element.

### DESCRIPTION OF THE DRAWINGS

The invention can be more fully understood by reading the subsequent detailed description in conjunction with the examples and references made to the accompanying drawings, wherein

FIG. 1 is a cross section of a conventional electronic device integrating a photovoltaic cell;

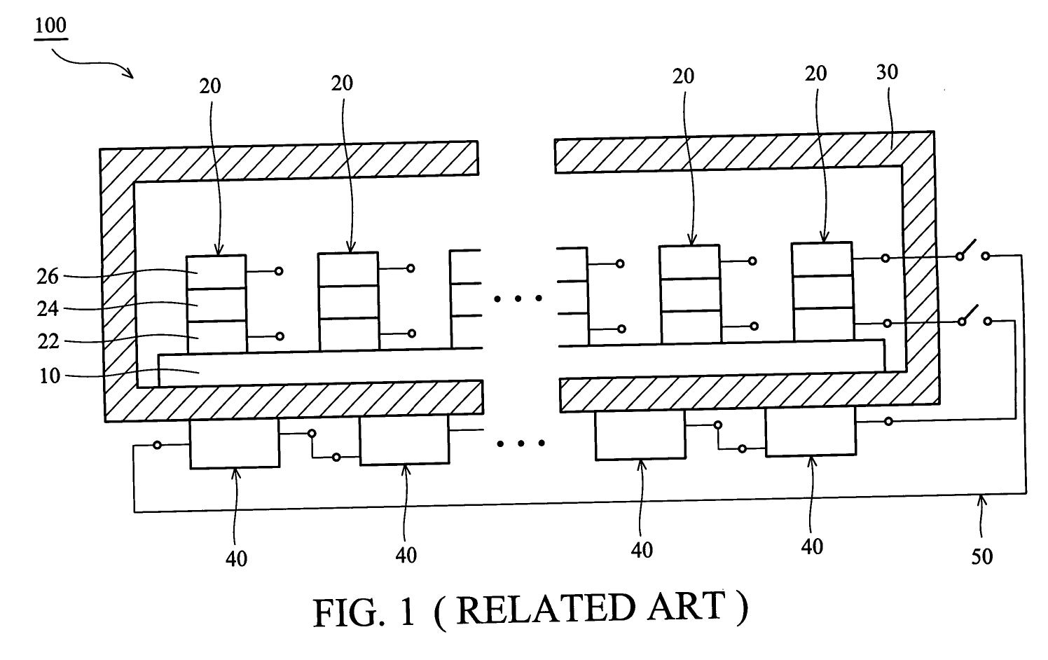

FIG. 2 is a cross section of an embodiment of an OLED display device integrating a photovoltaic cell; and

FIG. 3 is a cross section of another embodiment of an OLED display device 300 integrating a photovoltaic cell.

### DETAILED DESCRIPTION

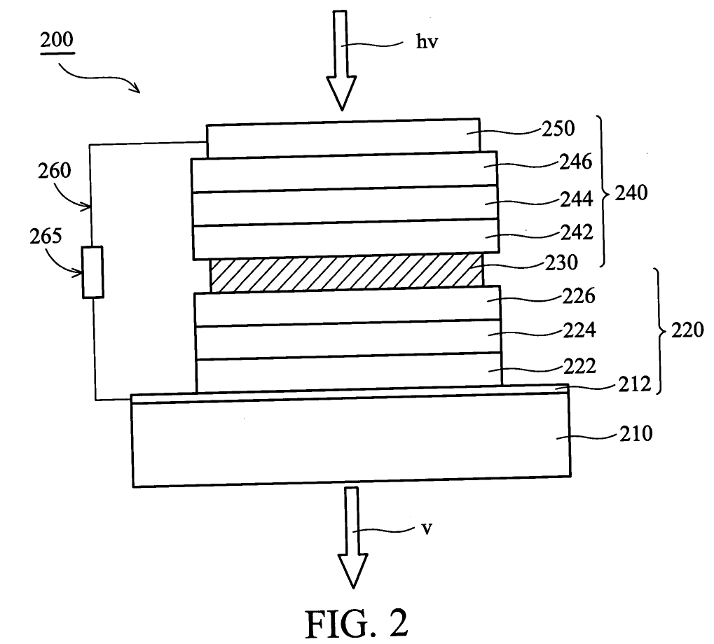

FIG. 2 is a cross section of an embodiment of an OLED display device 200 integrating a photovoltaic cell. Referring to FIG. 2, an OLED display device 200 comprises a substrate 210 with an OLED element 220 thereon. A photovoltaic cell 240 is disposed on the OLED element 220. The photovoltaic cell 240 can convert incident light hv into electricity to drive the OLED element 220. The OLED element 220 and the photovoltaic cell 240 share a common electrode 230.

The substrate 210 is a transparent substrate, such as a glass substrate or an active matrix substrate with a thin film transistor (TFT) array thereon.

The OLED element 220 may preferably comprise a bottom emission OLED element. More specifically, the OLED element 220 emits light toward the substrate 210 or in the direction of an observer (arrow v). The OLED element 220 may comprise a first electrode 212 such as a transparent electrode disposed on the substrate 210. The first electrode 212 comprises indium tin oxide (ITO), indium zinc oxide (IZO), aluminum zinc oxide (AZO), or zinc oxide deposited by sputtering, electron beam (e-beam) evaporation, thermal evaporation, chemical vapor deposition (CVD), or thermal spray decomposition.

An organic light emitting diode structure comprises a first hole transport layer 222 disposed on the first electrode 212. An organic light emitting layer 224 is disposed on the first hole transport layer 222. A first electron transport layer 226 is disposed on the organic light emitting layer 224. The first hole transport layer 222, organic light emitting layer 224, and first electron transport layer 226 comprise the OLED element 220. The organic light emitting layer 224 can be oligomer or polymer with single or multiple layers. The oligomer light emitting layer can be formed by thermal evaporation. Alternatively, the polymer light emitting layer can be formed by spin-on deposition, ink jet printing, or screen printing.

A second electrode 230 serving as a common electrode between the OLED element 220 and the photovoltaic cell 240 is disposed on the first electron transport layer 226. The second electrode 230 is an opaque electrode blocking light from the photovoltaic cell 240 into the OLED element 220. The second electrode 230 may comprise calcium (Ca), silver (Ag), magnesium (Mg), aluminum (Al), lithium (Li), or other low work function materials, or combinations thereof, formed by vacuum thermal evaporation or sputtering.

A photovoltaic cell 240 comprises an inorganic cell element or an organic cell element. According to an embodiment of the invention, the photovoltaic cell 240 can directly convert light into electricity by photovoltaic effect at a pn junction. Alternatively, the photovoltaic cell 240 can convert light into chemical energy, and then convert chemical energy into electricity.

The photovoltaic cell 240 preferably comprises an organic photovoltaic cell. The fabrication process of the organic photovoltaic cell 240 is compatible with the fabrication process of the OLED element 220. The photovoltaic cell 240 comprises a second electron transport layer 242 on the second electrode 230. A charge generation layer 244 is disposed on the second electron transport layer 242. A second hole transport layer 246 is disposed on the charge generation layer 244. When incident light is transmitted into the charge generation layer 244, electrons and holes are separately generated and transported into the second electron transport layer 242 and the second hole transport layer 246. A third electrode 250 such as a transparent electrode is disposed on the second hole transport layer 246. The third electrode 250 comprises indium tin oxide (ITO), indium zinc oxide (IZO), aluminum zinc oxide (AZO), or zinc oxide deposited by sputtering, electron beam (e-beam) evaporation, thermal evaporation, chemical vapor deposition (CVD), or thermal spray decomposition.

The third electrode 250 connects to the first electrode 212 through an external circuit 260, comprising a capacitor 265.

In some embodiments of the invention, the first electrode can be a first cathode. The second electrode 230 can be a common anode. The third electrode 250 can be a second cathode. Alternatively, the first electrode 212 can be a first anode. The second electrode 230 can be a common cathode. The third electrode 250 can be a second anode.

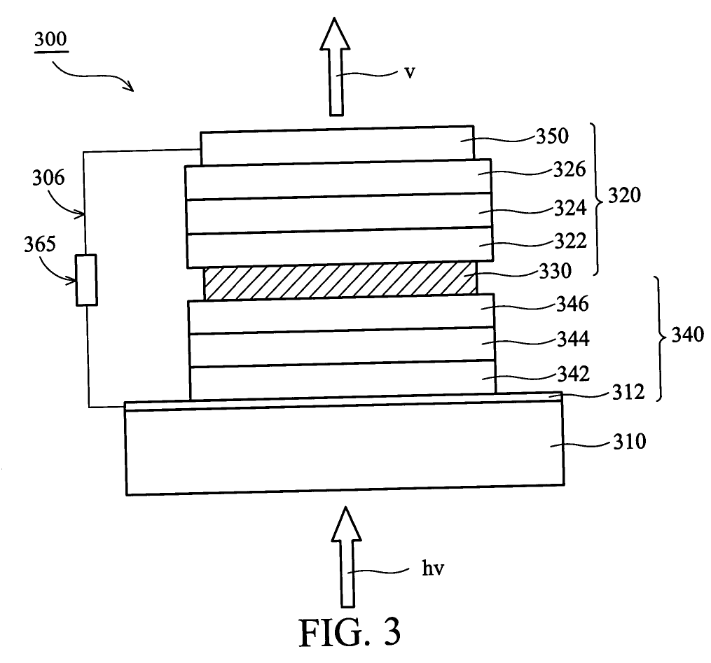

FIG. 3 is a cross section of another embodiment of an OLED display device 300 integrating a photovoltaic cell. Referring to FIG. 3, an OLED display device 300 comprises a substrate 310. A photovoltaic cell 340 is disposed on the substrate 310. An OLED element 320 is disposed on the photovoltaic cell 340. The photovoltaic cell 340 can convert incident light hv into electricity to drive the OLED element 320. The OLED element 320 and the photovoltaic cell 340 share a common electrode 330.

The substrate 310 is a transparent substrate, such as a glass substrate or an active matrix substrate with a thin film transistor (TFT) array thereon.

The photovoltaic cell 340 comprises an inorganic cell element or an organic cell element. In some embodiments of the invention, the photovoltaic cell 340 can directly convert light into electricity by photovoltaic effect at a pn junction. Alternatively, the photovoltaic cell 240 can convert light into chemical energy, and then convert chemical energy into electricity.

The photovoltaic cell 340 may preferably comprise an organic photovoltaic cell. The fabrication process of the organic photovoltaic cell 340 is compatible with the fabrication process of the OLED element 320. The photovoltaic cell 340 comprises a first electrode 312 such as a transparent electrode disposed on the substrate 310. The first electrode 312 comprises indium tin oxide (ITO), indium zinc oxide (IZO), aluminum zinc oxide (AZO), or zinc oxide deposited by sputtering, electron beam (e-beam) evaporation, thermal evaporation, chemical vapor deposition (CVD), or thermal spray decomposition. A second electron transport layer 342 is disposed on the first electrode 312. A charge generation layer 344 is disposed on the second electron transport layer 342. A second hole transport layer 346 is disposed on the charge generation layer 344. When incident light is transmitted into the charge generation layer 344, electrons and holes are separately generated and transported into the second electron transport layer 342 and the second hole transport layer 346.

A second electrode 330 is disposed on the electron transport layer 324 acting as a common electrode between the OLED element 320 and the photovoltaic cell 340. The second electrode 330 is an opaque electrode blocking light from the photovoltaic cell 340 into the OLED element 320. The second electrode 330 may comprise calcium (Ca), silver (Ag), magnesium (Mg), aluminum (Al), lithium (Li), or other low work function materials, or combinations thereof, formed by vacuum thermal evaporation or sputtering.

The organic light emitting diode element 320 may preferably comprise a top emission OLED element. More specifically, the OLED element 320 emits light toward the direction of an observer (arrow v). The OLED element 320 comprises a first hole transport layer 322 disposed on the second electrode 330. An organic light emitting layer 324 is disposed on the first hole transport layer 322. An electron transport layer 326 is disposed on the organic light emitting layer 322. The first hole transport layer 322, organic light emitting layer 324, and first electron transport layer 326 comprise the organic light emitting diode element 320. The organic light emitting layer 324 can be oligomer or polymer with single or multiple layers. The oligomer light emitting layer can be formed by thermal evaporation. Alternatively, the polymer light emitting layer 324 can be formed by spin-on deposition, ink jet printing, or screen printing.

A third electrode 350 such as a transparent electrode is disposed on the first electron transport layer 326. The third electrode 350 comprises indium tin oxide (ITO), indium zinc oxide (IZO), aluminum zinc oxide (AZO), or zinc oxide deposited by sputtering, electron beam (e-beam) evaporation, thermal evaporation, chemical vapor deposition (CVD), or thermal spray decomposition.

The third electrode 350 connects to the first electrode 312 through an external circuit 360, comprising a capacitor 365.

The first electrode can be a first cathode. The second electrode 330 can be a common anode. The third electrode 350 can be a second cathode. Alternatively, the first electrode 312 can be a first anode. The second electrode 330 can be a common cathode. The third electrode 350 can be a second anode.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An organic light emitting diode (OLED) display, comprising:
a first electrode;
a second electrode disposed opposite to the first electrode;
a conductive layer disposed between the first electrode and the second electrode;
an OLED element disposed between and coupled to the first electrode and the conductive layer; and
a photovoltaic cell element, disposed between and coupled to the conductive layer and the second electrode, for converting incident light into electricity to drive the OLED element.

2. The OLED display as claimed in claim 1, wherein the OLED element is adapted to radiate light in a direction away from the photovoltaic cell.

3. An organic light emitting diode (OLED) display, comprising:
a substrate;
a first electrode disposed on the substrate;
a second electrode disposed opposite to the first electrode;
a conductive layer disposed between the first electrode and the second electrode;
an organic light emitting diode (OLED) element disposed between and coupled to the first electrode and the conductive layer; and
a photovoltaic cell element, disposed between and coupled to the conductive layer and the second electrode, for converting incident light into electricity to drive the OLED element.

4. The OLED display as claimed in claim 3, wherein the OLED element comprises a bottom emission OLED element.

5. The OLED display as claimed in claim 3, wherein the first electrode comprises a transparent conductive layer.

6. The OLED display as claimed in claim 3, wherein the conductive layer comprises an opaque electrode.

7. The OLED display as claimed in claim 3, wherein the organic light emitting diode element comprises:
a first hole transport layer disposed on the first electrode;
a light emitting layer disposed on the first hole transport layer; and
a first electron transport layer disposed on the light emitting layer;
wherein the first electron transport layer electrically contacts the conductive layer.

8. The OLED display as claimed in claim 3, wherein the photovoltaic cell comprises:
a second electron transport layer disposed on the conductive layer;
a charge generation layer disposed on the second electron transport layer; and
a second hole transport layer disposed on the charge generation layer; wherein
the second electrode disposed on the second hole transport layer.

9. The OLED display as claimed in claim 8, wherein the second electrode comprises a transparent conductive layer.

10. The OLED display as claimed in claim 9, wherein the second electrode is adapted to electrically connect to the first electrode through an external circuit.

11. The OLED display as claimed in claim 10, wherein the external circuit comprises a capacitor.

12. The OLED display as claimed in claim 8, wherein the first electrode is a first cathode, the conductive layer is a common electrode, and the second electrode is a second cathode.

13. The OLED display as claimed in claim 8, wherein the first electrode is a first anode, the conductive layer is a common electrode, and the second electrode is a second anode.

14. An organic light emitting diode (OLED) display comprising:
a substrate;
a first electrode disposed on the substrate;
a second electrode disposed opposite to the first electrode;
a conductive layer disposed between the first electrode and the second electrode;
an organic light emitting diode (OLED) element disposed between and coupled to the second electrode and the conductive layer; and
a photovoltaic cell element, disposed between and coupled to the conductive layer and the first electrode, for converting incident light into electricity to drive the OLED element.

15. The OLED display as claimed in claim 14, wherein the OLED element comprises a top emission OLED element.

16. The OLED display as claimed in claim 14, wherein the photovoltaic cell comprises:
a first hole transport layer disposed on the first electrode;
a charge generation layer disposed on the first hole transport layer; and
a first electron transport layer disposed on the charge generation layer; wherein
the conductive layer is disposed on the first electron transport layer.

17. The OLED display as claimed in claim 14, wherein the first electrode comprises a transparent conductive layer.

18. The OLED display as claimed in claim 14, wherein the conductive layer comprises an opaque electrode.

19. The OLED display as claimed in claim 15, wherein the top emission OLED element comprises:
a second electron transport layer disposed on the conductive layer;
an organic light emitting layer disposed on the second electron transport layer; and
a second hole transport layer disposed on the organic light emitting layer; wherein
the second electrode is disposed on the second hole transport layer.

20. The OLED display as claimed in claim 16, wherein the second electrode comprises a transparent conductive layer.

21. The OLED display as claimed in claim 16, wherein the second electrode is adapted to electrically connect to the first electrode through an external circuit.

22. The OLED display as claimed in claim 21, wherein the external circuit comprises a capacitor.

23. The OLED display as claimed in claim 19, wherein the first electrode is a first cathode, the conductive layer is a common electrode, and the second electrode is a second cathode.

24. The OLED display as claimed in claim 19, wherein the first electrode is a first anode, the conductive layer is a common electrode, and the second electrode is a second anode.
